(19) United States
(12) Patent Application Publication
(10) Pub. No.: US 2025/0280490 A1
(43) Pub. Date: Sep. 4, 2025

(54) CONTROL DEVICE FOR A VEHICLE

(71) Applicant: HELLA GMBH & CO. KGAA, Lippstadt (DE)

(72) Inventors: Lothar-Michael Maduch, Lippetal (DE); Martin Ramme, Büren (DE)

(21) Appl. No.: 19/065,358

(22) Filed: Feb. 27, 2025

(30) Foreign Application Priority Data
Mar. 4, 2024 (DE) 102024106189.8

(51) Int. Cl. H05K 1/02

(52) U.S. Cl. CPC H05K 1/0216; H05K 1/0201; H05K 2201/032; H05K 2201/037; H05K 2201/066; H05K 2201/10303; H05K 2201/10409

(57) ABSTRACT

The invention relates to a control device for a vehicle. The control device includes a printed circuit board on which a plurality of electronic components is arranged. The control device also includes a body which is manufactured from an electrically conductive material. The printed circuit board is fastened to the body at a plurality of fastening points. A coupling device is provided which is designed such that the printed circuit board is capacitively coupled to the body in the region between the fastening points. The coupling device includes an electrically conductive pin provided on the body and an opening formed on the printed circuit board having an electrically conductive peripheral layer, the pin extending into the opening.

### CROSS-REFERENCE TO RELATED APPLICATIONS

The present application claims the benefit of German Patent Application No. 10-2024-106-189.8, filed Mar. 4, 2024, the disclosure of which is incorporated by reference.

### BACKGROUND OF THE INVENTION

The invention relates to a control device for a vehicle. The control device has a printed circuit board on which a plurality of electronic components is arranged, as well as a body which is manufactured from an electrically conductive material, the printed circuit board being fastened to the body at a plurality of fastening points.

Such a control device is disclosed, for example, in DE 10-2014-215-230 A1. The control device has a printed circuit board and a body, in this case a housing, wherein the printed circuit board is arranged in the housing and is fastened, in particular screwed on, to the housing at a few fastening points. A plurality of electronic components is arranged on the printed circuit board. The electronic components can generally be arranged on both sides of the printed circuit board.

The problem is that during the assembly of such control devices due to manufacturing and assembly tolerances of the body and the printed circuit board and during operation of the control device due to thermal expansion of the components of the control device, a gap can form between the fastening points, with a height and length in the range such that the gap acts like an antenna, in particular in the form of a slot antenna. As a result, electromagnetic radiation caused by electronic components arranged on the printed circuit board, in particular electronic components arranged on a side of the printed circuit board facing the body, is radiated into the environment through the gap. With a relatively large distance between the fastening points between the printed circuit board and the body, a relatively long gap can form, wherein electromagnetic radiation is radiated into the environment in such a frequency range that predefined EMC (electromagnetic compatibility) requirements can no longer be met. Such predefined EMC requirements serve to ensure that other components adjacent to the control unit are not disturbed by unwanted electrical or electromagnetic effects caused by the control device. The interfering electromagnetic radiation relevant to EMC requirements is substantially in the MHz frequency range.

In order to meet the EMC requirements, the length of the potentially forming gap, i.e. the distance between the fastening points, can be shortened by increasing the number of fastening points. On the one hand, this reduces the probability that a gap is present and, on the other hand, even if a gap is present, the length of the gap can be reduced in such a way that the electromagnetic radiation radiating into the environment has such a high frequency that the EMC requirements can be met despite the gap.

The disadvantage of this approach is that the provision of a plurality of fastening points and thus the requirement for a plurality of fastening means to be mounted considerably increases the assembly effort of the control device.

### SUMMARY OF THE INVENTION

The object of the invention is to provide a control device in which the emission of electromagnetic radiation can be influenced in a simple and cost-effective manner in such a way that the EMC requirements can be met. The object is achieved by embodiments of the invention.

According to one embodiment, a coupling device is provided which is designed such that the printed circuit board is capacitively coupled to the body in the region between the fastening points. The coupling device includes an electrically conductive pin provided on the body and an opening formed on the printed circuit board with at least one electrically conductive peripheral layer, the pin engaging in the opening. The pin engages in the opening in such a way that the pin is radially surrounded by the peripheral layer of the opening or by the peripheral surface of the opening.

Capacitive coupling is understood to mean that the pin is radially spaced from the peripheral layer on the peripheral side, at least in sections. In the case of a sectional, peripheral contact between the pin and the peripheral layer, a capacitive coupling is also present.

The coupling device is used to set the length of the potentially resulting gap, which acts as a slot antenna and forms in particular due to manufacturing tolerances and thermal expansion of the components, to a predefined length, i.e. to the distance between a fastening point and the point of the pin or the opening, wherein the position of the pin or the opening is selected in such a way that the frequency of any electromagnetic radiation caused by the resulting gap is in a frequency range that is irrelevant for the EMC requirements. In particular, the coupling device shortens the gap potentially acting as a slot antenna to such a length that the frequency of the electromagnetic radiation radiating into the environment is shifted to the GHz frequency range and thus the EMC requirements, for which electromagnetic radiation in the MHz frequency range is substantially relevant, can be met.

Because the coupling device is composed of a pin fastened to the body and an opening provided on the printed circuit board with an electrically conductive peripheral layer, the coupling device can be implemented in a simple and cost-effective manner. When mounting the control device, i.e. mounting or fastening the circuit board to the body, only the pin needs to be inserted into the opening and then the circuit board needs to be fixed to the body at a few fastening points using fastening means. Additional fastening points and associated fastening means to prevent the formation of a slot antenna, which would result in EMC requirements not being met, are not required. In addition, the pin and the opening can be used for pre-positioning when mounting the printed circuit board to the body before the printed circuit board is attached to the body at the fastening points using fastening means.

The pin can be manufactured in one piece with the body, which is optionally made of aluminum. This reduces the manufacturing and assembly effort. In particular, there is no need to fasten the pin to the body, which reduces the assembly effort. Alternatively, the pin can be designed as a separate element and can be fastened to the body. The pin can, for example, be a bolt pressed into an opening in the body or a screw screwed into the body.

In another embodiment, the pin and the peripheral layer of the opening are spaced apart. This causes a capacitive coupling between the body and the printed circuit board. The electrically conductive pin and the opening with the electrically conductive peripheral layer thus form a capacitor, in particular a cylindrical capacitor. Optionally, the pin and the opening with the peripheral layer are cylindrical, with the diameter of the pin being smaller than the diameter of the opening including the peripheral layer.

Because the pin is radially spaced from the peripheral layer of the opening on the peripheral side, the pin can be arranged in the opening in a displacable manner. This enables capacitive coupling between the printed circuit board and the body in the region between the two fastening points, regardless of the gap height. Depending on the height of the gap, the pin protrudes more or less into the opening.

In another embodiment, the printed circuit board is connected to the body at the fastening points by a plurality of screws. For example, the circuit board is screwed to the body with three screws. By minimizing the number of screws required to fasten the circuit board to the body, the assembly effort of the control device can be reduced. However, due to the small number of screws or fastening points, there is an increased risk of an undesirable gap forming in the region between the fastening points due to manufacturing tolerances and thermal expansion, which gap acts as a slot antenna. The gap is to be understood in such a way that the printed circuit board and the body are not electrically connected to each other in the region of the gap. A component, for example an adhesive or a heat-conducting paste, which is electrically non-conductive, can be arranged in the gap. As already explained in a previous paragraph, the length of the gap acting as a slot antenna is shortened by the coupling device in such a way that the electromagnetic radiation radiating into the environment is in such a frequency range that it is irrelevant in an EMC test. Despite the coupling device, the assembly effort is not increased as the pin is already inserted into the opening when the printed circuit board is placed on the body.

Optionally, the electrically conductive peripheral layer is manufactured by a coating process of an inner peripheral surface of the opening. This allows the electrically conductive peripheral layer, in particular a metallic layer, optionally a copper layer, to be provided in a simple and reliable manner on the peripheral surface of the opening. Due to the coating process, the peripheral layer can have a relatively thin thickness.

In another embodiment, the body is a heat sink and the printed circuit board is thermally connected to the body. The body thus serves to cool the printed circuit board, wherein the printed circuit board or the electronic components arranged on the printed circuit board heat up during operation and must be cooled to ensure functional operation. The heat sink has a plurality of cooling fins on a side facing away from the printed circuit board and towards the environment, which increase the heat transfer surface between the heat sink and the environment, thereby increasing the cooling effect. In order to specifically dissipate heat from the electronic components, the printed circuit board is optionally connected to the heat sink via a heat-conducting element, in particular a heat-conducting paste or a heat-conducting adhesive, at least in the region of the electronic components. The heat-conducting element expands when the temperature increases, which increases the risk of an unwanted gap caused by the heat-conducting element, wherein due to the coupling device the potentially resulting gap can be neglected.

### BRIEF DESCRIPTION OF THE DRAWING

The invention is explained in more detail below with reference to the accompanying drawing. In the figures:

FIG. 1 is a schematic cross-section of a control device for a vehicle.

### DETAILED DESCRIPTION OF THE CURRENT EMBODIMENT

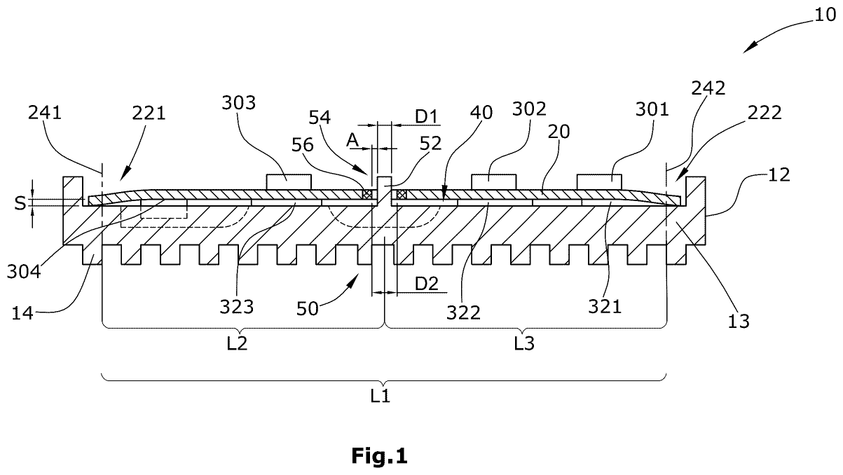

FIG. 1 shows a control device 10 for a vehicle. The control device 10 substantially comprises a body 12 and a printed circuit board 20.

The printed circuit board 20 is fastened or screwed to the body 12 at a plurality of fastening points 221, 222 by means of a screw 241, 242 in each case, the printed circuit board 20 resting against an in particular offset edge region 13 of the body 12 and being fastened to the edge region 13.

Electronic components 301, 302, 303, 304 are arranged both on a side facing away from the body 12 and on a side of the printed circuit board 20 facing the body 12, which are electrically connected to each other and to other components via conductor tracks not shown. The printed circuit board 20 or the electronic components 301, 302, 303, 304 heat up during operation and must be cooled. Therefore, the body 12 is designed as an aluminum heat sink and has a plurality of cooling fins 14 on a side facing away from the printed circuit board 20 and facing the outside environment in order to increase the heat transfer surface on the environment side and improve the cooling effect. The heat transfer between the body 12 and the printed circuit board 20 or the electronic components 301, 302, 303 takes place in particular in such a way that heat-conducting elements 321, 322, 323, for example in the form of a heat-conducting paste, are provided on the printed circuit board 20 in the region of the electronic components 301, 302, 303, by means of which the printed circuit board 20 or the electronic components 301, 302, 303 are thermally connected to the body 12, which is designed as a heat sink.

Due to manufacturing and assembly tolerances of the body 12 and the printed circuit board 20 as well as due to thermal expansion of the components of the control device 10 and the expansion of the heat-conducting elements 321, 322, 323, a gap 40 with a gap height S can form in the edge region 13 in the region between the fastening points 221, 222, which acts like an antenna, in particular in the form of a slot antenna. As a result, electromagnetic radiation, which is caused in particular by the electronic component 304 arranged on the side of the printed circuit board 20 facing the body 12, is radiated into the environment through the gap 40. With a relatively large distance L1 between the fastening points 221, 222, a gap 40 can form that is so long that the electromagnetic radiation is radiated into the environment in such a frequency range that specified EMC (electromagnetic compatibility) requirements can no longer be met.

In order to be able to meet the EMC requirements despite the potentially existing gap 40, the control device 10 has a coupling device 50, by means of which the printed circuit board 20 is capacitively connected to the carrier 12, the coupling device 50 being arranged between the two fastening points 221, 222. The coupling device 50 is formed by an electrically conductive pin 52 formed on the body 12 and an opening 54 formed on the printed circuit board 20 with an electrically conductive peripheral layer 56. In the final assembled state, the pin 52 protrudes into the opening 54, wherein the pin 52 only has to be inserted into the opening 54 when the printed circuit board 20 is attached to the carrier 12.

The pin 52 protrudes from the body 12 in the direction of the printed circuit board 20 and is manufactured in one piece with the body 12. The pin 52 has a cylindrical shape with a diameter D1. The opening 54 is also cylindrical and has a diameter D2 including the peripheral layer 56. The peripheral layer 56 is made of copper and is applied to a peripheral surface of the opening 54 by a coating process.

The capacitive coupling of the printed circuit board 20 to the body 12 is designed such that the diameter D1 of the pin 52 is smaller than the diameter D2 of the opening 54 such that the pin 52 and the peripheral layer 56 are arranged at a distance A radially spaced apart from one another, at least in sections.

By such a coupling device 50, the length of the potentially resulting gap 40 acting as a slot antenna is set to a predefined length L2, L3, i.e. the distance between a fastening point 221, 222 and the location of the pin 52 or the opening 54, the position of the coupling device 50 being selected such that the frequency of the electromagnetic radiations caused by the resulting gap 40 is shifted in such a high frequency range that it is irrelevant for the EMC requirements.

### LIST OF REFERENCE NUMERALS

10 control device
12 body
13 edge offset
20 printed circuit board
221 fastening point
222 fastening point
241 screw
242 screw
301 electronic component
302 electronic component
303 electronic component
304 electronic component
321 heat-conducting element
322 heat-conducting element
323 heat-conducting element
40 gap
50 coupling device
52 pin
54 opening
56 peripheral layer
A distance
D1 diameter of the pin
D2 diameter of the opening including the peripheral layer
S gap height
L1 distance between the fastening points
L2 distance between one of the fastening points and the coupling device
L3 distance between one of the fastening points and the coupling device

The above description is that of current embodiment of the invention. Various alterations and changes can be made without departing from the spirit and broader aspects of the invention. This disclosure is presented for illustrative purposes and should not be interpreted as an exhaustive description of all embodiments of the invention or to limit the scope of the claims to the specific elements illustrated or described in connection with these embodiments. Any reference to elements in the singular, for example, using the articles “a,” “an,” “the,” or “said,” is not to be construed as limiting the element to the singular.

1. A control device for a vehicle, comprising:
a printed circuit board on which a plurality of electronic components is arranged;
a body which is formed from an electrically conductive material, the printed circuit board being fastened to the body at first and second fastening points; and
a coupling device, the coupling device being configured such that the printed circuit board is capacitively coupled to the body in a region between the first and second fastening points, the coupling device comprising an electrically conductive pin on the body and an opening in the printed circuit board, the printed circuit board having an electrically conductive peripheral layer within the opening, the pin extending into the opening in the printed circuit board.

2. The control device of claim 1, wherein the pin is integrally formed with the body.

3. The control device of claim 1, wherein the pin and the peripheral layer are radially spaced apart from each other.

4. The control device of claim 1, wherein the printed circuit board is spaced from the body in the region between the first and second fastening points such that a gap is present.

5. The control device of claim 1, wherein the pin and the peripheral layer are cylindrical, and wherein an outer diameter of the pin is smaller than an inner diameter of the peripheral layer.

6. The control device of claim 1, wherein the printed circuit board is connected to the body at the first and second fastening points by a screw in each instance.

7. The control device of claim 1, wherein the electrically conductive peripheral layer is manufactured by a coating process.

8. The control device of claim 1, wherein the electrically conductive peripheral layer is made of copper.

9. The control device of claim 1, wherein the body is a heat sink and wherein the printed circuit board is thermally connected to the body.

10. The control device of claim 1, wherein the printed circuit board is connected to the body in sections via at least one heat-conducting element.

11. The control device of claim 1, wherein the body is made of aluminum.
